(19) United States
(12) Patent Application Publication
(10) Pub. No.: US 2020/0266089 A1
(43) Pub. Date: Aug. 20, 2020

(54) CARRIER AND METHOD FOR MANUFACTURING SEMICONDUCTOR DEVICE

(71) Applicants: KABUSHIKI KAISHA TOSHIBA, Minato-ku (JP); Kioxia Corporation, Minato-ku (JP)

(72) Inventors: Kazuo SHIMOKAWA, Yokohama (JP); Takayuki TAJIMA, Sagamihara (JP)

(73) Assignees: KABUSHIKI KAISHA TOSHIBA, Minato-ku (JP); Kioxia Corporation, Minato-ku (JP)

(21) Appl. No.: 16/743,072

(22) Filed: Jan. 15, 2020

(30) Foreign Application Priority Data
Feb. 20, 2019 (JP) 2019-028074

(51) Int. Cl. H01L 21/683; B32B 43/00; B32B 38/10; C09J 7/20; H01L 21/56; C09J 5/00

(52) U.S. Cl. CPC H01L 21/6835; B32B 43/006; B32B 38/10; H01L 2221/68386; H01L 21/568; C09J 5/00; C09J 2203/326; C09J 7/20

(57) ABSTRACT

According to one embodiment, a carrier includes a support substrate; a release layer provided on the support substrate; a first adhesion layer provided between the support substrate and the release layer; and a protective layer provided between the support substrate and the first adhesion layer. A thickness of the protective layer is thicker than a thickness of the release layer and a thickness of the first adhesion layer.

### CROSS-REFERENCE TO RELATED APPLICATION

This application is based upon and claims the benefit of priority from Japanese Patent Application No. 2019-028074, filed on Feb. 20, 2019; the entire contents of which are incorporated herein by reference.

### FIELD

Embodiments described herein relate generally to a carrier and a method for manufacturing a semiconductor device.

### BACKGROUND

A new packaging technology called FO-WLP (Fan Out Wafer Level Package) is being developed. In FO-WLP, interconnects are formed on a support substrate; mounting processes such as chip mounting, sealing, etc., are performed; subsequently, the sealed parts are peeled from the support substrate; and the packages are completed by singulation.

Front-end process equipment is used to manufacture products in which a high-definition interconnect pitch is formed; therefore, the support substrate that is used is glass or a silicon wafer. Because glass and silicon wafers account for a high proportion of the total cost, it is desirable to re-utilize the support substrate.

### BRIEF DESCRIPTION OF THE DRAWINGS

FIG. 1 is a schematic cross-sectional view of a carrier according to an embodiment of the invention;

FIG. 2A to FIG. 9B are schematic cross-sectional views showing a method for manufacturing a semiconductor device according to the embodiment of the invention;

FIG. 10 is a schematic top view showing a method for manufacturing the semiconductor device according to the embodiment of the invention; and

FIG. 11 is a schematic cross-sectional view of a carrier according to the embodiment of the invention.

### DETAILED DESCRIPTION

According to one embodiment, a carrier includes a support substrate; a release layer provided on the support substrate; a first adhesion layer provided between the support substrate and the release layer; and a protective layer provided between the support substrate and the first adhesion layer. A thickness of the protective layer is thicker than a thickness of the release layer and a thickness of the first adhesion layer.

Embodiments of the invention will now be described with reference to the drawings. In the drawings, the same components are marked with the same reference numerals; and a detailed description is omitted as appropriate. The drawings are schematic; and the relationships between the thicknesses and widths of portions, the proportions of sizes among portions, etc., are not necessarily the same as the actual values. The dimensions and/or the proportions may be illustrated differently among the drawings, even for identical portions.

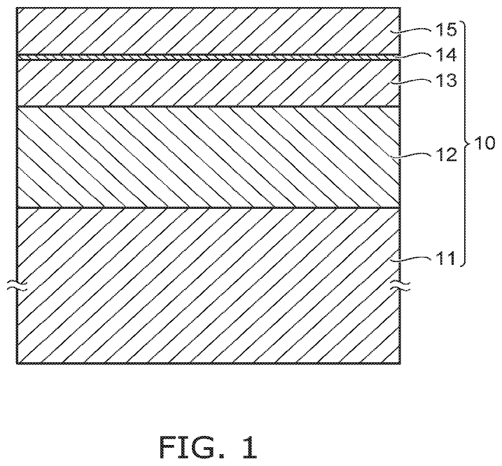

FIG. 1 is a schematic cross-sectional view of a carrier 10 according to an embodiment of the invention.

The carrier 10 includes a support substrate 11, a protective layer 12, a first adhesion layer (hereinbelow, also called simply the adhesion layer) 13, a release layer 14, and a metal layer 15. The protective layer 12, the adhesion layer 13, the release layer 14, and the metal layer 15 are provided in order on the support substrate 11.

The support substrate 11 is, for example, a silicon substrate or a glass substrate. The thickness of the support substrate 11 is thicker than the thickness of the protective layer 12, the thickness of the adhesion layer 13, the thickness of the release layer 14, and the thickness of the metal layer 15. The thickness of the support substrate 11 is, for example, about 1 mm.

The thickness of the adhesion layer 13 is 5 μm or less, and more favorably 1 μm or less, e.g., about 0.5 μm. The thickness of the release layer 14 is 1000 nm or less, favorably 100 nm or less, and more favorably 10 nm or less, e.g., several nm. The thickness of the metal layer 15 is 5 μm or less, and more favorably 1 μm or less, e.g., about 0.5 μm.

The thickness of the protective layer 12 is thicker than the thickness of the adhesion layer 13, the thickness of the release layer 14, and the thickness of the metal layer 15. The thickness of the protective layer 12 is, for example, 1 μm or more, favorably 5 μm or more, and more favorably 10 μm or more. The protective layer 12 may be formed at two surfaces of the support substrate 11. The warp of the wafer due to a thick protective layer 12 can be suppressed thereby.

The protective layer 12 is made of an oxide or a metal including at least one selected from the group consisting of Al, Ti, V, Cr, Fe, Co, Ni, Cu, Ge, Rb, Y, Zr, Nb, Mo, Rh, Pd, Ag, Sn, Sm, Gd, Dy, Er, Hf, Ta, W, Re, Os, Ir, Pt, Au, Th, and U. Or, the protective layer 12 is a resin layer.

The adhesion layer 13 and the metal layer 15 each may include a material including the same metal as the protective layer 12. The adhesion layer 13 is at least one layer and may be formed of two or more layers. For example, the adhesion of the layer structure having the adhesion layer 13 interposed can be improved by the adhesion layer 13 including a layer of a material having good adhesion with the release layer 14 and a layer of a material having good adhesion with the protective layer 12. The metal layer 15 also is at least one layer and may be formed of two or more layers.

The release layer 14 includes, for example, carbon as a major component. The adhesion layer 13 is, for example, a metal layer which increases the adhesion between the protective layer 12 and the release layer 14.

For example, the metal layer 15 functions as a seed layer for plating. The metal layer 15 functions also as a cover layer which covers the surface of the release layer 14 and protects the surface of the release layer 14 from contamination, etc.

In the case where the protective layer 12 is a material including a metal, for example, it is easy to increase the film thickness by forming by plating. Or, the protective layer 12 may be formed by sputtering or vapor deposition.

Interconnect formation on the carrier 10 without a break occurring is possible by setting the TTV (Total Thickness Variation) of the protective layer 12 to be 10 μm or less, favorably 5 μm or less, and more favorably 1 μm or less.

Due to the nm-order thickness of the release layer 14, the surface roughness (e.g., Ra) of the protective layer 12 is 0.1 μm or less, favorably 0.01 μm or less, and more favorably 0.001 μm or less. Also, the desired TTV and Ra may be ensured by surface polishing after forming the protective layer 12.

In the case where the protective layer 12 is a resin layer, the protective layer 12 can be formed by a method such as compression molding, transfer molding, inkjet molding, or the like of a thermoplastic resin or a thermosetting resin. In such a case as well, the desired TTV and Ra can be ensured by surface polishing after forming the resin layer.

For example, the protective layer 12, the adhesion layer 13, the release layer 14, and the metal layer 15 can be formed continuously inside the same chamber by sputtering by changing the target.

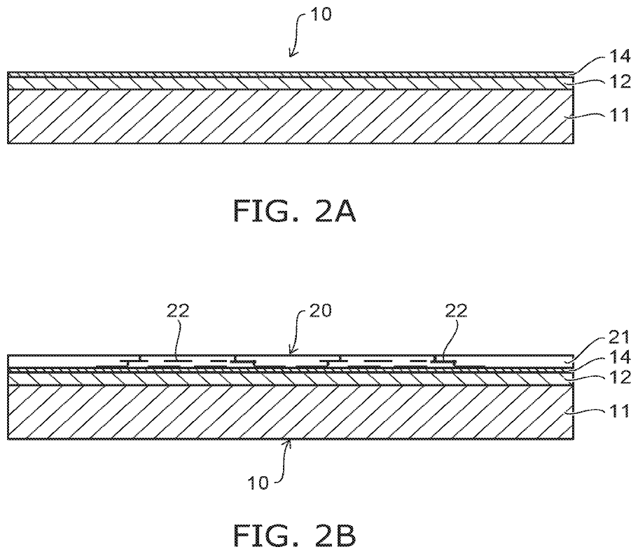

FIG. 2A to FIG. 5B are schematic cross-sectional views showing a method for manufacturing a semiconductor device using the carrier 10.

First, the carrier 10 described above is prepared as shown in FIG. 2A. The adhesion layer 13 and the metal layer 15 shown in FIG. 1 are not illustrated in the cross-sectional views showing the manufacturing method in FIG. 2A and subsequent drawings.

As shown in FIG. 2B, an interconnect layer 20 is formed on the carrier 10. The interconnect layer 20 includes multiple interconnects 22, and an insulating layer 21 insulating between the multiple interconnects 22. The interconnects 22 are metal interconnects and include, for example, Cu. The interconnects 22 each may be single layers or multiple layers.

A resist is formed on the metal layer 15 shown in FIG. 1. A plating resist is formed by patterning the resist by exposing and developing. Then, the interconnects 22 are formed on the metal layer 15 exposed at the plating resist by plating using the metal layer 15 as a seed layer. Subsequently, the plating resist is removed. Subsequently, the insulating layer 21 is formed. When forming multiple layers of interconnects 22, processes of forming vias in the insulating layer 21, plating processes of forming the interconnects 22 of the upper layers, etc., are continued.

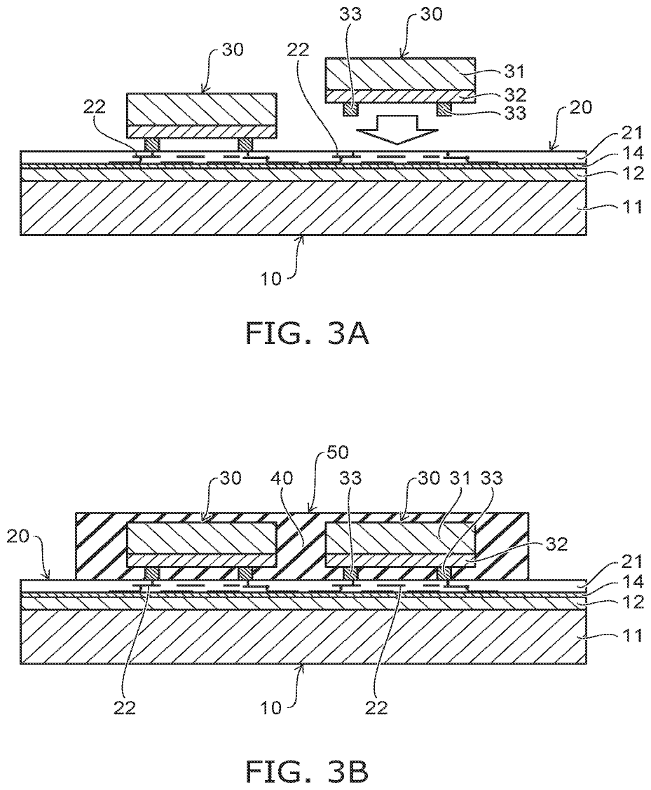

As shown in FIG. 3A, a semiconductor element 30 is mounted on the interconnect layer 20. The semiconductor element 30 includes a semiconductor layer 31, an on-chip interconnect layer 32, and an electrode 33. The semiconductor element 30 is electrically connected to the interconnect 22 of the interconnect layer 20 by bonding the electrode 33 to the interconnect 22.

After the semiconductor element 30 is mounted on the interconnect layer 20, the semiconductor element 30 is covered with a resin material 40 as shown in FIG. 3B. A resin plate 50 which includes the semiconductor element 30 and the resin material 40 covering the semiconductor element 30 is formed on the interconnect layer 20.

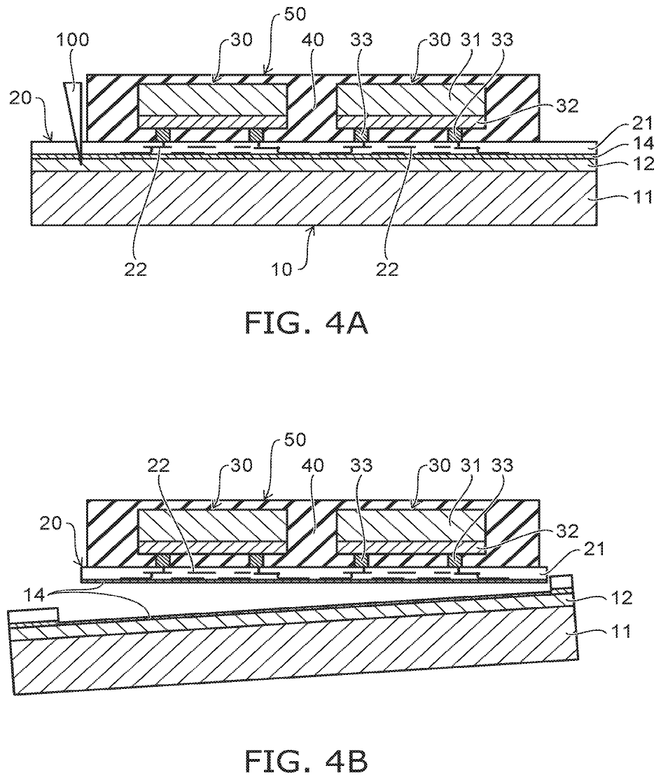

After the resin plate 50 is formed, a portion of the release layer 14 is fractured using, for example, a jig 100 such as a knife, etc., as shown in FIG. 4A.

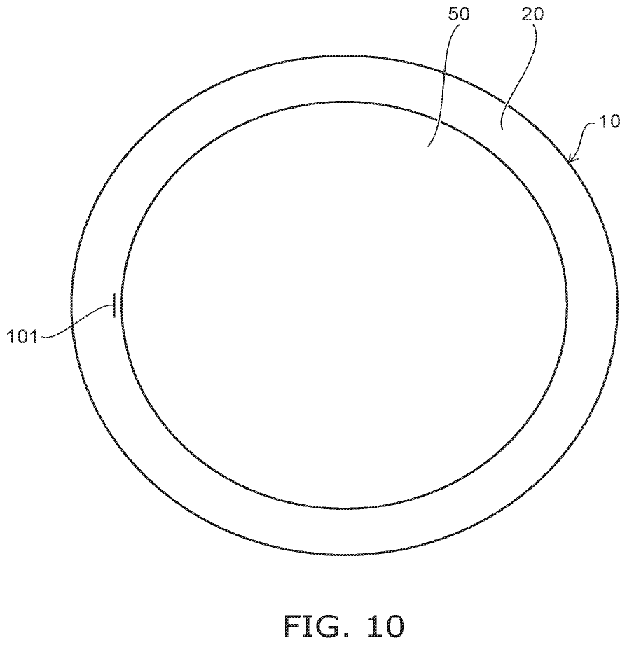

FIG. 10 is a schematic top view of the structure body of FIG. 4A.

For example, the resin plate 50 is not formed on the outer perimeter portion of the carrier 10 in the circular wafer state. A fracture portion 101 is formed by the jig 100 in a portion of the outer perimeter portion.

The interconnect layer 20, the metal layer 15, the release layer 14, and the adhesion layer 13 are fractured in the thickness direction by the jig 100; and the tip of the jig 100 reaches the protective layer 12. The fracture portion stops in the protective layer 12 and does not reach the support substrate 11. Accordingly, the support substrate 11 is not scratched by the jig 100.

After the fracture portion is formed, the support substrate 11 is peeled from the resin plate 50 by using the fracture portion as a starting point. For example, the support substrate 11 is peeled by vacuum-attaching to the support substrate 11 along the support substrate 11 from the side proximal to the fracture portion in a state in which the resin plate 50 side is fixed on a stage by dicing tape.

As shown in FIG. 4B, the support substrate 11 and the resin plate 50 detach at the release layer 14. For example, the release layer 14 is divided into a portion attached to the resin plate 50 side and a portion attached to the support substrate 11 side.

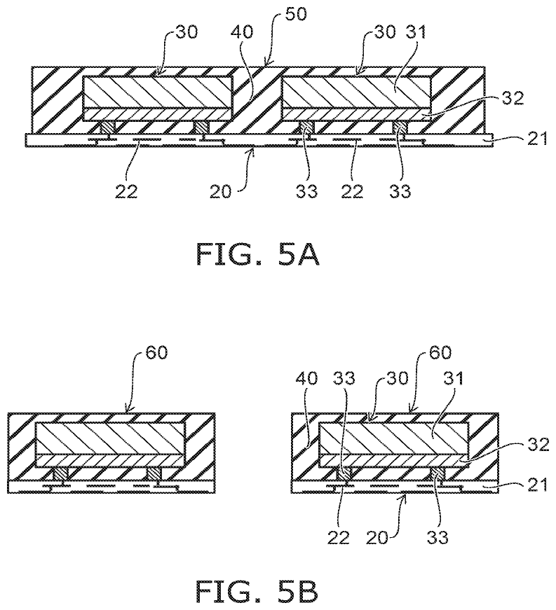

For example, the release layer 14 that is attached to the interconnect layer 20 on the resin plate 50 side is removed by etching. Subsequently, for example, the metal layer 15 also is removed by etching. The support substrate 11 is peeled; and as shown in FIG. 5A, the surface of the interconnect layer 20 is exposed on the side opposite to the surface where the resin plate 50 is formed. A metal film for external connection is formed by electroplating or electroless plating on portions (pads) of the interconnects 22 exposed at the surface. Solder balls and/or metal bumps also are formed as necessary.

Subsequently, the resin plate 50 and the interconnect layer 20 are cut and singulated into multiple semiconductor devices 60 as shown in FIG. 5B.

Currently, peeling methods of the support substrate are being developed in which the release layer releases due to a material modification caused by irradiating a laser beam, or in which the start (the fracture portion) of the peeling is made by a knife or the like in the release layer and the peeling is performed mechanically.

From a cost perspective, mechanical peeling is drawing attention because an expensive laser device is not used; but it is challenging to reduce costs because the support substrate cannot be re-utilized due to damage of the support substrate when forming the start (the fracture portion) of the peeling.

According to the embodiment, the protective layer 12 is formed between the support substrate 11 and the release layer 14 and stops the blade tip of the knife used to form the fracture portion used as the start of the peeling; therefore, the support substrate 11 can be peeled without damaging the support substrate 11. Therefore, re-utilization of the support substrate 11 is possible; and the process cost can be reduced.

In other words, the release layer 14 and the metal layer that remain on the peeled support substrate 11 are removed; and the carrier 10 shown in FIG. 1 is re-prepared subsequently by re-forming the release layer 14 and the metal layer 15. The protective layer 12 and the adhesion layer 13 also may be re-formed. Or, the protective layer 12 may not be re-formed, and can be re-utilized by polishing the surface scratched by the previous use. Then, the resin plate 50 is re-formed on the re-prepared carrier 10 by the processes described above.

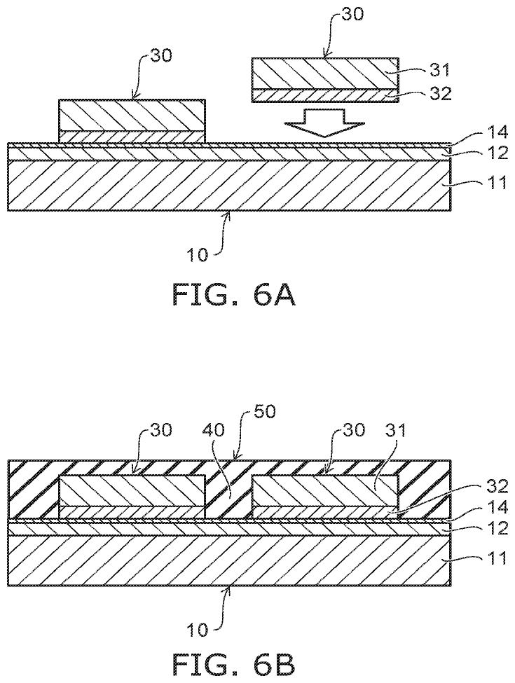

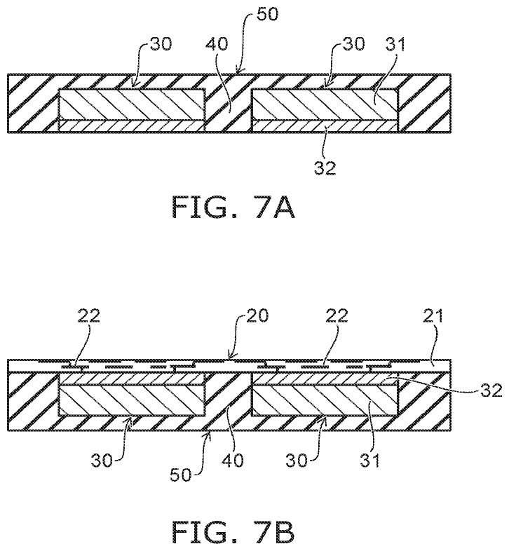

FIG. 6A to FIG. 7B are schematic cross-sectional views showing another example of the method for manufacturing the semiconductor device using the carrier 10.

As shown in FIG. 6A, the semiconductor element 30 is mounted on the release layer 14 of the carrier 10. The on-chip interconnect layer 32 of the semiconductor element 30 opposes the release layer 14.

In the example, the plating seed layer which is on the release layer 14 may be unnecessary. Instead of the plating seed layer, a cover layer (an insulating film and/or a metal film) for protecting the surface of the release layer 14 may be formed; or a resin layer for bonding and adhering the semiconductor element 30 may be formed.

After the semiconductor element 30 is mounted on the carrier 10, as shown in FIG. 6B, the resin plate 50 is formed by covering the semiconductor element 30 with the resin material 40.

Subsequently, a method similar to the processes described above is used to peel the support substrate 11 from the resin plate 50 by forming a fracture portion in the release layer 14 and subsequently using the fracture portion as a starting point. In such a case as well, the fracture portion stops in the protective layer 12 and does not reach the support substrate 11.

The support substrate 11 is peeled; and the on-chip interconnect layer 32 of the semiconductor element 30 is exposed as shown in FIG. 7A. In the example, the resin layer and/or the metal layer formed on the release layer 14 is removed after peeling the support substrate 11 by etching, etc. As shown in FIG. 7B, the interconnect layer 20 is formed on the on-chip interconnect layer 32 and the surface of the resin material 40 on the on-chip interconnect layer 32 side. Subsequently, singulation into multiple semiconductor devices is performed similarly to the example described above.

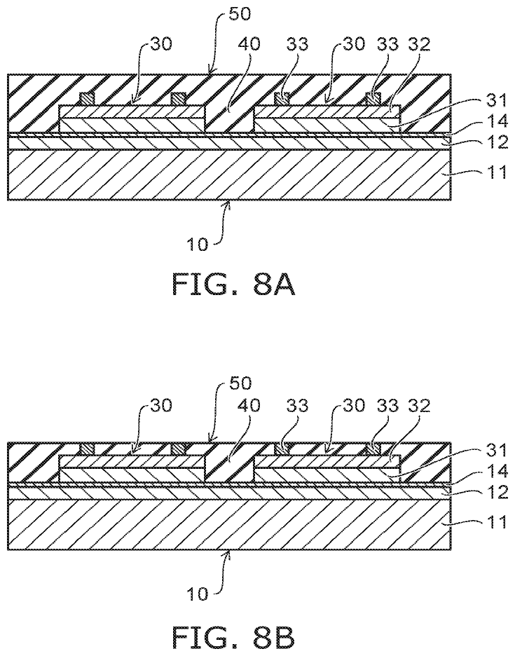

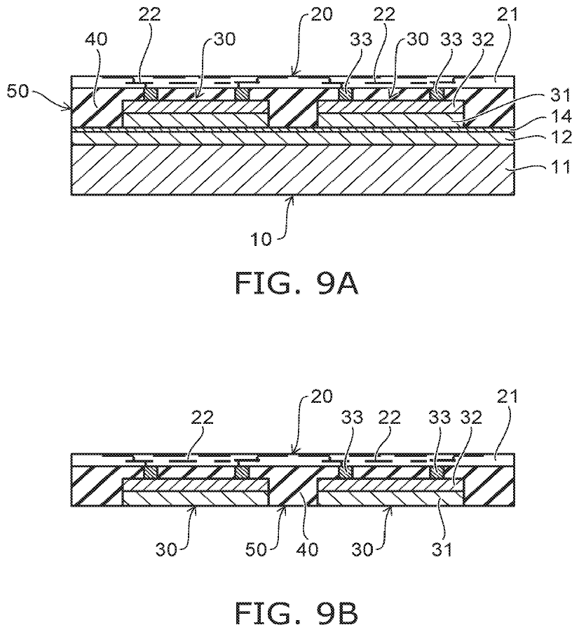

FIG. 8A to FIG. 9B are schematic cross-sectional views showing other examples of the method for manufacturing the semiconductor device using the carrier 10.

As shown in FIG. 8A, the semiconductor element 30 is mounted on the release layer 14 of the carrier 10. A resin material or a solder material is used to mount the semiconductor element 30. The electrode 33 and the on-chip interconnect layer 32 of the semiconductor element 30 are oriented away from the carrier 10.

In the example, the plating seed layer which is on the release layer 14 may be unnecessary. Instead of the plating seed layer, a cover layer (an insulating film and/or a metal film) for protecting the surface of the release layer 14 may be formed.

After the semiconductor element 30 is mounted on the carrier 10, the resin plate 50 is formed by covering the semiconductor element 30 with the resin material 40. Subsequently, for example, the surface of the resin material 40 is polished; and the electrode 33 of the semiconductor element 30 is exposed at the resin material 40 as shown in FIG. 8B.

As shown in FIG. 9A, the interconnect layer 20 is formed on the surface of the resin material 40 where the electrode 33 is exposed. The electrode 33 is connected to the interconnect 22 of the interconnect layer 20.

Subsequently, a method similar to the processes described above is used to peel the support substrate 11 from the resin plate 50 by forming a fracture portion in the release layer 14 and subsequently using the fracture portion as a starting point. In such a case as well, the fracture portion stops in the protective layer 12 and does not reach the support substrate 11.

Similarly to the examples described above, the structure body shown in FIG. 9B of which the support substrate 11 is peeled is singulated into multiple semiconductor devices.

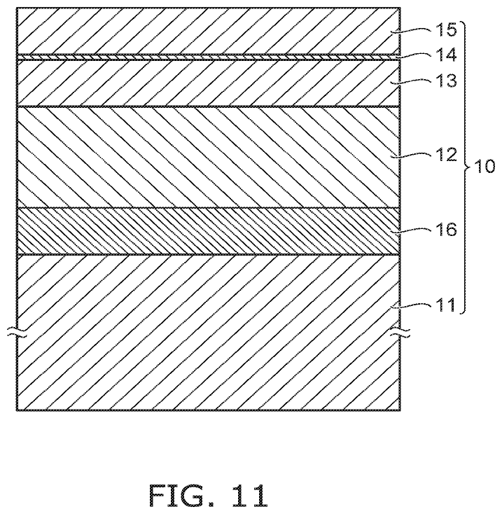

FIG. 11 is a schematic cross-sectional view of another example of the carrier 10.

In the example shown in FIG. 11, a second adhesion layer 16 is provided between the support substrate 11 and the protective layer 12. The adhesion between the support substrate 11 and the protective layer 12 can be increased by the second adhesion layer 16; and the degrees of freedom increase for the material selection of the protective layer 12 itself.

A thinner protective layer 12 can be used by forming a layer (e.g., a cemented carbide layer) which is harder than the jig 100 as the protective layer 12.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A carrier, comprising:
a support substrate;
a release layer provided on the support substrate;
a first adhesion layer provided between the support substrate and the release layer; and
a protective layer provided between the support substrate and the first adhesion layer, a thickness of the protective layer being thicker than a thickness of the release layer and a thickness of the first adhesion layer.

2. The carrier according to claim 1, wherein the protective layer is made of an oxide or a metal including at least one selected from the group consisting of Al, Ti, V, Cr, Fe, Co, Ni, Cu, Ge, Rb, Y, Zr, Nb, Mo, Rh, Pd, Ag, Sn, Sm, Gd, Dy, Er, Hf, Ta, W, Re, Os, Ir, Pt, Au, Th, and U.

3. The carrier according to claim 1, wherein the protective layer is a resin layer.

4. The carrier according to claim 1, further comprising a cover layer covering a surface of the release layer,
the protective layer being thicker than the cover layer.

5. The carrier according to claim 4, wherein the cover layer is a metal layer.

6. The carrier according to claim 1, further comprising a second adhesion layer provided between the support substrate and the protective layer.

7. A method for manufacturing a semiconductor device, comprising:
preparing a carrier, the carrier including a support substrate, a release layer provided on the support substrate, and a protective layer provided between the support substrate and the release layer;
forming a resin plate on the release layer, the resin plate including a semiconductor element and a resin material covering the semiconductor element;
forming a fracture portion in the carrier by fracturing the release layer in a thickness direction, the fracture portion reaching the protective layer but not reaching the support substrate; and
peeling the support substrate from the resin plate by using the fracture portion as a starting point.

8. The method according to claim 7, wherein
the carrier includes a metal layer provided on the release layer,
the method further comprises forming an interconnect layer on the release layer, the interconnect layer including an interconnect formed by patterning the metal layer, and
the resin plate is formed on the interconnect layer.

9. The method according to claim 7, further comprising forming an interconnect layer at a surface of the resin plate exposed by the peeling of the support substrate.

10. The method according to claim 7, further comprising forming an interconnect layer at a surface of the resin plate opposite to a surface of the resin plate supported by the carrier,
the peeling of the support substrate from the resin plate being after the forming of the interconnect layer.

11. The method according to claim 7, further comprising:
re-preparing the carrier by re-forming the protective layer and the release layer on the support substrate peeled from the resin plate; and
re-forming the resin plate on the re-formed release layer.
